(19) United States
(12) Patent Application Publication
(10) Pub. No.: US 2011/0223767 A1
(43) Pub. Date: Sep. 15, 2011

(54) CONTROL WAFER RECLAMATION PROCESS

(75) Inventors: Jin-Lin Liang, Alian Township (TW); Yu-Sheng Su, Tainan City (TW); Tai-Yung Yu, Rende Township (TW); Perre Kao, Tainan City (TW); Pin Chia Su, Shanhua Township (TW); Li Te Hsu, Shanhua Township (TW)

(73) Assignee: TAIWAN SEMICONDUCTOR MANUFACTURING CO., LTD., Hsin-Chu (TW)

(21) Appl. No.: 13/114,333

(22) Filed: May 24, 2011

Related U.S. Application Data
(63) Continuation of application No. 12/046,096, filed on Mar. 11, 2008, now abandoned.

(51) Int. Cl. H01L 21/311; B82Y 40/00

(52) U.S. Cl. 438/694; 977/888; 257/E21.249

(57) ABSTRACT

A method of recycling a control wafer having a low-k dielectric layer deposited thereon involves etching a portion of the low-k dielectric layer using a plasma resulting in a residual film of the low-k dielectric layer and byproduct particulates of carbon on the substrate. The residual dielectric film is removed by wet etching with a low polarization organic solvent that includes HF and a surfactant.

### RELATED APPLICATIONS

This application is a continuation of U.S. application Ser. No. 12/046,096 filed Mar. 11, 2008, which is expressly incorporated herein by reference in its entirety.

### FIELD

The present invention relates to a process for reclaiming control wafers.

### BACKGROUND

In modern semiconductor device technology, low-k dielectric material has been used to replace traditional silicon diode oxide as the inter-metal dielectric layers to improve the electrical performance of the semiconductor devices by suppressing signal-propagation delay, cross-talk between metal lines and power consumption due to their low dielectric constants. One of the promising low-k dielectric material is the trimethylsilane (TMS)-based dielectric material. The TMS-based dielectric material is an organosilicate glass with a dielectric constant as low as about 2.1.

Prior to forming a low-k dielectric layer on production wafers, the low-k dielectric layer usually is deposited on a control wafer to assure that physical and electrical characteristics of the low-k dielectric layer satisfy process requirements. Once these characteristics of the low-k dielectric layer deposited on the control wafer are verified to be within the desired range defined by the process specifications, the same recipe is used for the test wafer is set up to process the production wafers. After being processed, the control wafer must be transferred to a cleaning station where the low-k dielectric layer is removed and the control wafer's silicon substrate is recycled to be used again as a control wafer. This is also known as a reclaim procedure of control wafers.

FIG. 6 shows a cross-sectional view of a control wafer according to a conventionally known procedure for reclaiming control wafer. A traditional reclaim procedure of control wafers includes simply removing the whole low-k dielectric layer using HF or H₂SO₄ wet etchant. The traditional reclaim procedure results in residue 105 of the low-k dielectric material on the control wafer 100 as shown in FIG. 6. Residue 105 on the top surface of the control wafer 100 affects the deposition of low-k dielectric layers on the control wafer 100 during subsequent reuse of the control wafer 100. As a consequence, because the reclaimed control wafer substrate 100 is not representative of the virgin production wafer, the process recipe generated using the process parameters measured on the reclaimed control wafer would not be useful to run production wafers.

Other known methods involve removing the low-k dielectric layer from the control wafers by sandblasting or polishing. These mechanical removal process, however, remove some amount of the underlying silicon wafer substrate at each reclaim cycle and thus limit the number of times the control wafer substrate can be recycled.

### SUMMARY

According to an embodiment, a method of recycling a control wafer having a dielectric layer deposited thereon is disclosed. The method comprises plasma etching the dielectric layer using a plasma formed with a gas comprising CxFy gas, wherein the plasma etching is conducted for a determined time to leave a residual film of the dielectric layer on the substrate at the end of the plasma etching process, whereby the residual film protects the substrate from the plasma. The residual film of the dielectric layer is then removed by a wet etching process leaving behind a clean wafer that is ready to be reused as a control wafer.

According to another embodiment, a method of recycling a control wafer is disclosed. The method comprises providing the control wafer, the control wafer comprising a substrate, and forming a dielectric layer on the substrate. Then, the dielectric layer is plasma etched using a plasma formed with a gas comprising CxFy gas, wherein the plasma etching is conducted for a determined time to leave a residual film of the dielectric layer on the substrate at the end of the plasma etching process, whereby the residual film protects the substrate from the plasma. The residual film of the dielectric layer is then removed by a wet etching process leaving behind a clean wafer that is ready to be reused as a control wafer.

According to another embodiment, a method of recycling a control wafer having a dielectric layer deposited on a substrate is disclosed. The method comprises plasma etching the dielectric layer using a plasma formed with a gas comprising CxFy gas, wherein the plasma etching is conducted for a determined time to leave a residual film of the dielectric layer on the substrate at the end of the plasma etching process, whereby the residual film protects the substrate from the plasma. The residual film of the dielectric layer is then removed by a wet etching process at the end of which some byproduct particulates can remain on the substrate. The byproduct particulates are then cleaned by ammonia peroxide mixture followed by a brush scrubbing, leaving a clean substrate that can be reused as a control wafer.

The innovative method disclosed herein is suitable for all low-k dielectric film control wafers. The method is also suitable for all silicon-based substrate control wafers as well as gallium arsenide-based substrate control wafers.

### BRIEF DESCRIPTION OF THE DRAWINGS

FIG. 1 is a cross-sectional illustration of a already processed control wafer whose wafer substrate is ready to be reclaimed.

FIG. 2 is a process flow diagram illustrating different stages of the low-k dielectric layer on the control wafer being removed according to an embodiment of the disclosure.

FIG. 3 is a flowchart illustrating an embodiment of the control wafer reclamation method.

FIG. 4 is a schematic illustration of an example of a plasma etching chamber.

FIG. 5 is an illustration of the wet etching process portion of the method of an embodiment of the present disclosure.

FIG. 6 is a cross-sectional view of a process control wafer reworked with a conventional procedure for reclaiming a control wafer.

The features shown in the above referenced drawings are illustrated schematically and are not intended to be drawn to scale nor are they intended to be shown in precise positional relationship. Like reference numbers indicate like elements.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. The terms “reclaim” and “reclaiming” are used interchangeably herein with “recycle” and “recycling” to refer to the recovery of the semiconductor substrate portion of the control wafer through the method disclosed herein.

FIG. 1 is a cross-sectional view of an example of a control wafer 200 that has been processed to characterize a process for forming a porous low-k dielectric layer 203. The control wafer 200 at this stage comprises a wafer substrate 201 with the porous low-k dielectric layer 203 thereon. The wafer substrate 201 is usually a semiconductor material and can be, for example, a silicon-based substrate, a III-V compound substrate, a glass substrate, a gallium arsenide substrate, a printed circuit board (PCB) or any other substrate similar thereto. In this example, the wafer substrate 201 is a single-crystal silicon wafer. The low-k dielectric layer 203 contains a plurality of pores 10. The pores are formed by porogens, such as ATRP (α-Terpinene) (not shown), that are deposited along with the dielectric layer and then removed from the dielectric layer leaving behind pores in the dielectric layer.

The low-k dielectric layer 203 is made of an organosilicate material such as BD-II (Black Diamond II) available from Applied Materials, Inc. of Santa Clara, Calif. Such low-k dielectric material when deposited on the substrate 201 and cured is a porous material in which the porosity lends to the low-k value. The low-k dielectric material such as the BD-II may be characterized as carbon-doped silicon oxide (or silicon oxycarbide) having a carbon fraction of above 10 at %. Their porosity can be in the range of up to 30%. Other carbon-containing low-k dielectrics are known, including Silk and Cyclotene (benzocyclobutene) dielectric materials available from Dow Chemical. Many of these materials are characterized as organic or polymeric dielectrics. The low-k dielectric material layer 203 includes short-chain polymer structure that are adapted to be dissolved in organic solvents such as hydrofluoric acid-based etchants.

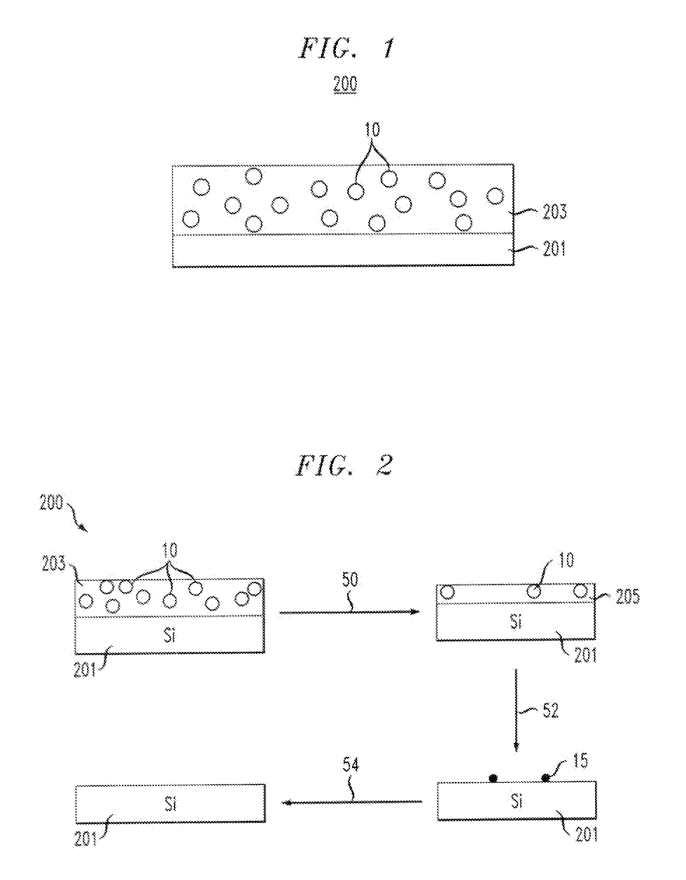

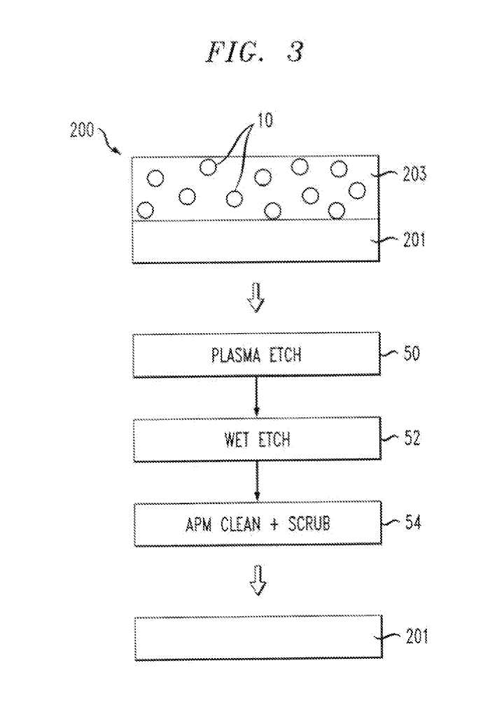

According to an embodiment of the present disclosure, FIG. 2 is a block diagram flow chart showing a method of reclaiming the wafer substrate 201 from a used control wafer 200. First, the control wafer 200 is processed through a plasma etch 50 process, a dry etching, that removes most of the porous low-k dielectric layer 203 and leaving a thin residual film 205 of the low-k dielectric layer.

Next, the residual low-k dielectric film 205 is removed by a wet etch process 52. The wet etch process 52 comprises dipping the control wafer 200 in a solution of a hydrofluoric acid-based organic etch solvent. As will be described in more detail below, the wet etch process 52 removes the residual film 205 but some byproduct particulates 15 of the wet etch process remain on the surface of the wafer substrate 201.

Next, the byproduct particulates 15 are removed by a cleaning process 54 which comprises Ammonia Peroxide Mixture (APM) clean and scrubbing. After the cleaning process 54, a clean wafer substrate 201 is obtained, that can be reused as a process control wafer. At the end of this process, a clean substrate 201 remains that is ready to be reused as a process.

Referring to FIG. 3, the details of the above-mentioned processes involved in removing the low-k dielectric removal according to an embodiment of the present disclosure will be described. The porous low-k dielectric layer 203 on the control wafer 200 is first dry etched by a plasma etch 50. A plasma etching is performed by applying electromagnetic energy, typically radio frequency energy, to a gas containing a chemically reactive element, such as fluorine or chlorine. The plasma releases positively charged ions that bombard the wafer to remove (etch) materials and chemically reactive free radicals that react with the etched material to form volatile or nonvolatile byproducts. Generally, when etching dielectric materials fluorine-based gas such as CxFy is used to generate the plasma. According to one preferred embodiment wherein the porous low-k dielectric layer 203 is an organosilicate material such as BD-II (Black Diamond II), a tetrafluoromethane (CF₄) gas plasma is used to dry etch the dielectric layer 203. The CF₄ gas plasma conditions are 200 W at 40 mbar. The plasma is continuously applied to the dielectric layer 203.

The duration of the plasma etching process 50 is optimized according to the particular thickness of the low-k dielectric layer 203 so that at the end of the plasma etching process, much of the porous low-k dielectric layer 203 is removed but not completely and a thin residual film 205 of the low-k dielectric layer is left behind. Stopping the plasma etching before the low-k dielectric layer is completely removed prevents the surface of the wafer substrate 201 from being damaged by the plasma etching process. The inventors have experimentally verified that without the residual film 205, plasma gas will damage the surface of the bare Si wafer substrate 201. In one preferred embodiment, the residual film 205 is approximately 300 to 1000 Å thick. Thus, the duration of the plasma etching process 50 depends on the starting thickness of the dielectric film. In one embodiment, for the starting thickness of the low-k dielectric film 203 of 2800 Å, the plasma etching with CF₄ gas plasma at 200 W at 40 mbar is at least about 65 seconds.

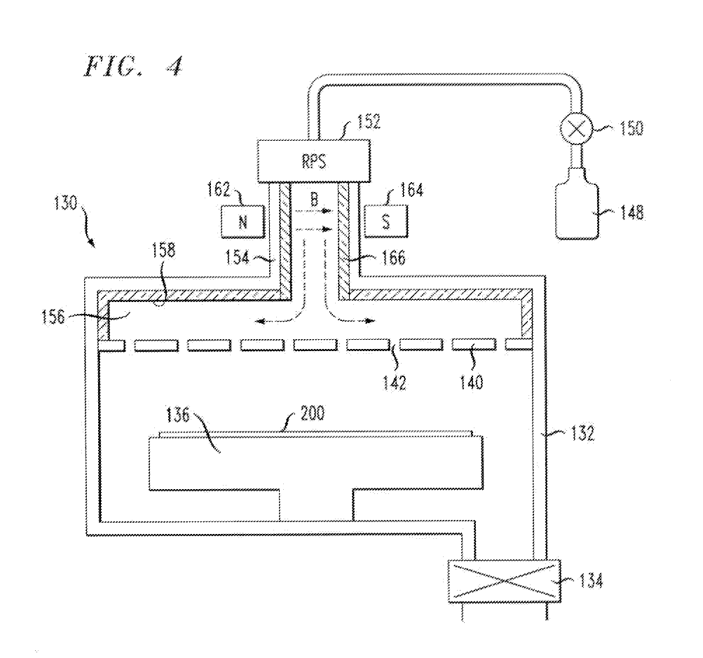

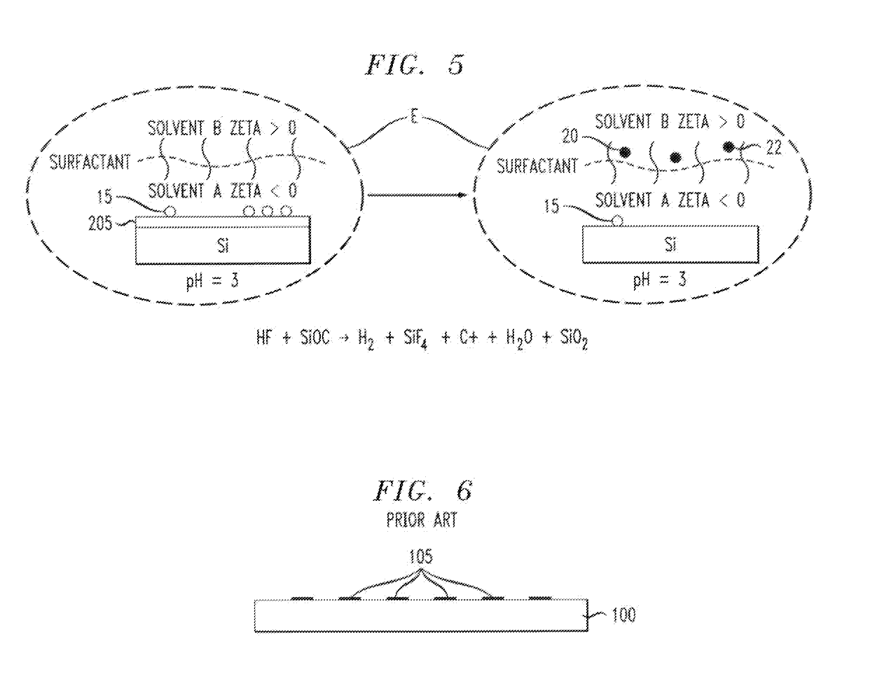

FIG. 4 is a cross-sectional illustration of an example of a plasma etching chamber 130 that may be used to perform the plasma etching process 50. The plasma etching chamber 130 includes a vacuum chamber 132 pumped by a vacuum pump system 134. A pedestal 136 within the chamber 136 supports a control wafer 200 to be etched in opposition to a gas showerhead 140 supplying a process gas (CF₄) through a large number of apertures 142. The pedestal 136 generally includes a heater to raise the temperature of the wafer 200 to a desired etching temperature. The process gas is supplied from a gas source 148 through a mass flow controller 150. A remote plasma source 152 receives the process gas and excites it into a plasma. In one example, the remote plasma source 152 may be a pair of electrodes positioned on opposed sides of a delivery tube for the process gas and driven by an RF power source or an RF inductive coil around the delivery tube or other type of antenna but other types of plasma generators can also be used. The excited gas (plasma) is delivered though a supply tube 154 to a gas manifold 156 in back of the showerhead 140. A liner 158 may cover the walls of the gas manifold 156. The excited gas is thus delivered uniformly through the showerhead 140 to the control wafer 200 being etched.

Referring back to FIG. 3, next, the control wafer substrate 201 with a residual film 205 of the low-k dielectric material and byproduct particulates 15 is processed through the wet etch process 52 for removing the residual film 205. The hydrofluoric acid-based etching solvent used in the wet etch process 52 can be halo-hydrocarbon, halo-aromatic compounds or hydro-aromatic compounds. In one preferred embodiment, the hydrofluoric acid-based organic etchant is CDO3.1 (also known as Regen Si-31) available from ATMI, Inc. of Danbury, Conn. The etchant includes HF acid and its pH value is between 3 to 7, the bare Silicon has a Zeta potential <0. Byproducts of the wet etch process 52 such as SiO₂ and C has a Zeta potential >0 and will be easily attracted to the bare Silicon surface as the residual low-k dielectric film 205 is etched away. As described in more detail below, the wet etch process 52 of this disclosure uses a mixed solvent of organic solvents A and B plus a surfactant that attracts the SiO₂ and C by product away from the surface of the bare Silicon.

The concentration of hydrofluoric acid in such etching solvent required to etch the low-k dielectric material is generally high and will etch the underlying wafer substrate 201 if etched too long. Thus, the pH level of the etching solution and the optimal etching duration time to remove the film needs to be controlled. The chemical composition of CDO3.1 is HF+a surfactant+organic solvent A+organic solvent B. And for the residual film 205 having a thickness of 300 to 1000 Å mentioned above, the control wafer 200 is dipped in a CDO3.1 solvent for an optimal time of about 120 seconds, where the HF concentration in CDO3.1 is approximately 19% and the pH of CDO3.1 is maintained at 3.

FIG. 5 is a graphical representation of the wet etching process 52 illustrating how a hydrofluoric acid (HF) based etchant E, such as CDO3.1, removes the residual low-k dielectric film 205. The chemical reaction is:

HF+SiOC→H₂+SiF₄+C⁺+H₂O+SiO₂

In this embodiment, the HF based etchant CDO3.1 comprises organic components solvent A, solvent B and a surfactant. The organic solvent A component of CDO3.1 is a higher polarization solvent and its Zeta potential is <0 at pH=3 and tends to be attracted to the bare silicon wafer substrate 201 surface whose Zeta potential at pH=3 is about −20 mV. The organic solvent B component of CDO3.1 is a lower polarization solvent and its Zeta potential is >0 at pH=3 and tends to repel from the bare silicon wafer substrate 201 surface. The surfactant component of CDO3.1 allows the organic solvent components A and B to be miscible. The mixed solvent behaves more like a lower polarization solvent. This allows the byproduct particulates 15, such as C⁺ 20 and SiO₂ 22 from the low-k dielectric material reacting with HF, to readily dissolve in the solvent B component of CDO3.1. Some examples of the suitable surfactant are long C-chain compounds. The wet etch process 52 comprises the mixed solvent formed from the organic solvents A and B because the inventors have experienced that using only HF to remove the residual low-k dielectric film 205 results in the byproduct particulates 15 being bonded to the bare silicon substrate 201 and not easily removed. An example of a solvent A is Dimethyl Sulfoxide and an example of a solvent B is Dioxane, both having solubility in water >0.95 as shown in Table 1 below. Table 1 shows the polarity index and water solubility of various solvents as a reference.

TABLE 1

| | | Solubility |
|---|---|---|
| Polarity Index | Solvent | in Water (%) |
| 0 | Heptane | 0.0003 |
| 0 | Hexane | 0.001 |
| 0 | Pentane | 0.004 |
| 0.2 | Cyclohexane | 0.01 |
| 1 | Trichloroethylene | 0.11 |
| 1.6 | Carbon Tetrachloride | 0.08 |
| 2.2 | Di-Iso-Propyl Ether | 0 |
| 2.4 | Toluene | 0.051 |
| 2.5 | Methyl-t-Butyl Ether | 4.8 |
| 2.5 | Xylene | 0.018 |
| 2.7 | Benzene | 0.18 |
| 2.8 | DiEthyl Ether | 6.89 |
| 3.1 | Dichloromethane | 1.6 |
| 3.5 | 1,2-Dichloroethane | 0.81 |
| 3.9 | Butyl Acetate | 7.81 |
| 3.9 | Iso-Propanol | 100 |
| 4 | n-Butanol | 0.43 |
| 4 | Tetrahydrofuran | 100 |
| 4 | n-Propanol | 100 |
| 4.1 | Chloroform | 0.815 |
| 4.4 | Ethyl Acetate | 8.7 |
| 4.7 | 2-Butanone | 24 |
| 4.8 | Dioxane | 100 |
| 5.1 | Acetone | 100 |
| 5.1 | Methanol | 100 |
| 5.2 | Ethanol | 100 |
| 5.8 | Acetonitrile | 100 |
| 6.2 | Acetic Acid | 100 |
| 6.4 | Dimethylformamide | 100 |
| 7.2 | Dimethyl Sulfoxide | 100 |
| 9 | Water | 100 |

One of the aspects of the method disclosed herein that facilitates the effective removal of the residual low-k dielectric film 205 using the wet etch process 52 is that, during the plasma etch 50, the chemical bond among the polymer chains in the low-k dielectric layer 203 changes and the remaining residual low-k dielectric film 205 is of the type that is more easily dissolved during the wet etch process 52. During the plasma etch 50, some CF₄ gas molecules that has not transformed into plasma form accompany the plasma and the non-plasma CF₄ gas molecules transfer energy to the low-k dielectric layer and induce the low-k dielectric film to change its chemical bond characteristics.

Referring back to FIG. 2, at the end of the wet etch 52, although the residual film 205 of the low-k dielectric material is completely removed, some of the byproduct particulates 15 still may remain on the surface of the substrate 201. Next, the byproduct particulates 15 that remain on the substrate are removed in the cleaning process 54. The cleaning process 54 includes cleaning the wafer substrate 201 with APM clean followed by brush scrubbing process. In one embodiment, the APM clean can be implemented in a conventional wet bench cleaning chamber, such as KAIJO wet bench. The brush scrubbing process is carried out in a chamber tool using a H₂O₂ based solvent and a spinning brush. The brush scrubbing removes the byproduct particulares 15. After the cleaning process 54, a clean wafer substrate 201 that is ready to be used again as a process control wafer emerges.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention. Thus, the method of the present disclosure provides a process sequence of dry etching then wet etching for reclaiming control wafers.

What is claimed is:

1. A method of recycling a control wafer comprising:
providing the control wafer comprising a substrate;
forming a low-k dielectric layer on the substrate;
etching a portion of the low-k dielectric layer using a plasma resulting in a residual film of the low-k dielectric layer and byproduct particulates comprising carbon on the substrate; and,
removing the residual film of low-k dielectric layer by wet etching with a low polarization organic solvent comprising HF and a surfactant.

2. The method of claim 1, wherein the plasma is formed with a gas comprising CxFy gas.

3. The method of claim 1, wherein the substrate is a semiconductor substrate

4. The method of claim 2, wherein the plasma etching comprises etching with CF₄ plasma gas for at least 65 seconds.

5. The method of claim 1, wherein the residual film of low-k dielectric layer has a thickness of 300 to 1000 Å.

6. The method of claim 1, wherein the wet etching comprises etching with a hydrofluoric acid-based etchant comprising a low polarization organic solvent whose Zeta potential is >0 at pH of 3.0 and a high polarization organic solvent whose Zeta potential is <0 at pH of 3.0.

7. The method of claim 1, wherein the wet etching duration is at least 120 seconds.

8. The method of claim 1, further comprising cleaning the substrate with ammonia peroxide mixture followed by brush scrubbing of the substrate.

9. The method of claim 1, wherein the surfactant is a long C-chain compound.

10. A method of recycling a control wafer comprising:
providing the control wafer comprising a substrate;
forming a dielectric layer having pores and carbon on the control wafer;
plasma etching the dielectric layer using a plasma, wherein the plasma etching is conducted for a determined time leaving behind a portion of the dielectric layer on the substrate, whereby the portion of the dielectric layer protects the control wafer from the plasma;
removing the portion of the dielectric layer by wet etching with an organic solvent comprising HF, and a surfactant; and
cleaning the control wafer.

11. The method of claim 10, wherein the plasma is formed with a gas comprising CxFy gas.

12. The method of claim 10, wherein the substrate is a semiconductor substrate.

13. The method of claim 11, wherein the plasma etching comprises etching with CF₄ plasma gas for at least 65 seconds.

14. The method of claim 10, wherein the portion of the dielectric layer has a thickness of 300 to 1000 Å.

15. The method of claim 10, wherein the organic solvent is a low polarization organic solvent.

16. The method of claim 10, wherein the organic solvent includes a low polarization organic solvent whose Zeta potential is >0 at pH of 3.0 and a high polarization organic solvent whose Zeta potential is <0 at pH of 3.0.

17. The method of claim 10, wherein the wet etching wet etching duration is at least 120 seconds.

18. The method of claim 10, wherein the cleaning the control wafer involve cleaning with ammonia peroxide mixture followed by brush scrubbing of the substrate.

19. A method of recycling a control wafer comprising:
providing the control wafer comprising a silicon substrate;
forming a dielectric layer on the silicon substrate;
plasma etching the dielectric layer using a CF₄ plasma gas, wherein the plasma etching is conducted for a determined time leaving behind a residual film of the dielectric layer having a thickness of 300 to 1000 Å on the silicon substrate, whereby the residual film protects the entire silicon substrate from the plasma;
removing the residual film of dielectric layer by wet etching with a hydrofluoric-based etchant comprising a low polarization organic solvent whose Zeta potential is >0 at pH of 3.0 and a high polarization organic solvent whose Zeta potential is <0 at pH of 3.0.

20. The method of claim 19, wherein one or more byproduct particulates remain on the substrate after the wet etching process and the method further comprising cleaning the one or more byproduct particulates.
